(19) United States
(12) Patent Application Publication
(10) Pub. No.: US 2009/0092472 A1
(43) Pub. Date: Apr. 9, 2009

(54) Apparatus and system for handling a glass sheet

(76) Inventors: Weiwei Luo, Painted Post, NY (US); Samuel Odei Owusu, Painted Post, NY (US); Ye Guang Pan, Painted Post, NY (US); Babak Robert Raj, Elmira, NY (US); Yawei Sun, Horseheads, NY (US); Naiyue Zhou, Painted Post, NY (US)

Correspondence Address: CORNING INCORPORATED, SP-TI-3-1, CORNING, NY, 14831, US

(21) Appl. No.: 12/154,782

(22) Filed: May 27, 2008

Related U.S. Application Data
(60) Provisional application No. 60/931,779, filed on May 25, 2007.

(51) Int. Cl. H01L 21/64; H01L 21/677; B25J 15/06

(52) U.S. Cl. 414/752.1; 414/222.02; 414/217; 414/806; 901/40

(57) ABSTRACT

A method of conveying a glass substrate utilizing an improved non-contact lifting device. The non-contact lifting device employs the Bernoulli effect to create a pressure differential across the glass substrate. The Bernoulli device of the present invention comprises an increased holding or lifting power, and reduces the opportunity for contact between the device and the glass substrate if the device is tilted with respect the plane of the glass substrate surface.

### CROSS-REFERENCE TO RELATED APPLICATIONS

This application claims the benefit of priority under 35 U.S.C. § 119(e) of U.S. Provisional Application Ser. No. 60/931,779 filed on May 25, 2007.

### BACKGROUND OF THE INVENTION

1. Field of the Invention

This invention relates to an apparatus for holding and/or conveying a thin substrate sheet, and in particular a large glass sheet.

2. Technical Background

A variety of conveying methods are known for transporting and manipulating thin substrates, and in particular circular semiconductor substrates. However, semiconductor substrates are generally on the order of about 15 cm in diameter and not prone to significant flexure. In many of these semiconductor applications, pickup or “end effector” devices operate on the Bernoulli principal, and a single Bernoulli device (e.g. chuck) is sufficient to accommodate the substrate.

Display devices, on the other hand, such as liquid crystal display devices for use in televisions, continue to grow in size, requiring ever larger glass substrate panels from which the devices are manufactured. Some substrate panels can have a one-side surface area in excess of 3 square meters, and in some cases at least about 10 square meters, yet have a thickness equal to or less than 0.7 mm. Handling such large panels of exceptionally thin glass is a challenge in and of itself. However, compounding the difficulty is that the surface of the glass must be maintained in as pristine a condition as possible. Thus, customer requirements directed to the surface condition of the substrate panels are exceptionally stringent.

One glass making process in particular that is capable of producing extremely large sheets of very thin glass is the fusion downdraw process. Briefly, molten glass is flowed over converging forming surfaces, rejoining at the bottom of the converging surfaces and drawn to form a thin ribbon of glass. The ribbon solidifies as it descends, and is eventually separated into individual glass sheets at the bottom of the drawing area. As can be appreciated, the process is continuous, and the solid glass ribbon at the bottom of the draw area is intimately connected to the viscous ribbon of glass flowing from the bottom of the converging forming surfaces. Thus, motion of the ribbon at the bottom of the draw, e.g. during the cutting (separating) process may be translated upward to the viscous region of the ribbon. To wit, this motion can result in stresses that may become frozen into the solidifying ribbon, and ultimately manifest themselves as distortion in the separated glass sheet. Moreover, the glass ribbon at the bottom of the draw, while cooled to the point that the glass is solid, is nevertheless still quite hot (approximately 350° C.), further complicating handling. In other parts of the process, the surface condition of the glass sheet may vary, e.g. dry, wet or coated with a plastic film. Systems designed for transporting and manipulating semiconductor substrates are incapable of transporting such large, thin substrate sheets under such diverse conditions.

It should also be noted that the ribbon of glass descending from the converging forming surfaces takes on a slight curve or bow across the width of the ribbon (transverse to the direction of flow). Thus, the method used to acquire the glass sheet on the draw should be capable of accommodating this curvature.

Today when a glass sheet (e.g., liquid crystal display (LCD) glass sheet) is manufactured a robot is often used to move the glass sheet from one point to another point in a glass manufacturing facility. A robot, as used herein, refers generally to a machine (e.g. electrical, hydraulic, pneumatic or a combination thereof) that performs predetermined tasks automatically, usually under the control of a computer. Robots find extensive use in manufacturing environments to perform rote or precision tasks, and are heavily used, for example, in the automotive industry. Robots often include articulated arms or appendages with specialized ends to facilitate the intended function. For example, the arms may include devices for grasping, drilling, cutting and so forth. The robot used in moving glass sheets typically comprises an end effector that uses a plurality of suction cups to engage and hold the outside edges or non-quality area of the glass sheet. The outside edges are later removed and discarded, leaving only the interior “quality” area of the sheet. The suction cups need to engage the glass sheet on the outer edges only because if they contact the glass sheet in the center portion of the quality area then unacceptable defects or contamination may be created in the glass sheet. Because the glass sheet is hot, suction cups also deteriorate quickly, and must be constantly replaced, adding to manufacturing costs. Furthermore, engagement of the suction cups with the glass sheet causes undesirable vibration of the sheet.

As customers require larger and larger glass sheets it becomes increasingly more difficult for the robot to engage and move the glass sheet without causing motion in the center portion of the glass sheet. The motion in the center portion of the glass sheet is caused because there is a long, unsupported span in the middle of the glass sheet. Of course, the glass sheet can possibly break or even fall off the suction cups if the robot causes too much motion in the glass sheet. One way to minimize the motion in the glass sheet is to limit the speed of the robot. A drawback of this approach is that a large cycle time is required by the robot to move the glass sheet from one point to another point in the glass manufacturing facility.

While every effort is made to maintain conditions of cleanliness in the manufacturing operation, the danger of particulate contamination of the suction cups, however pliant the suction cups might be, is a constant danger, as such particulate can damage the substrate surface. To wit, anytime there is contact with the surface of the substrate, the potential for damaging the substrate is present. Thus, there has been considerable effort to develop non-contact methods of handing large glass substrates.

US Patent Publication 2006/0042315, for example, discloses the use of Bernoulli chucks to support the quality area of the glass sheets, thereby augmenting the use of suction cups. However, the sheer size and weight of present day, and anticipated future, generations (e.g. sizes) of glass sheet, and the suction cup issues above, begs for an enhancement to this approach.

### SUMMARY

In accordance with an embodiment of the present invention an aero-mechanical device is disclosed comprising a body portion comprising an inlet for receiving a gas, a cavity defined by the body portion in fluid communication with the inlet for equalizing a velocity of the gas, an outlet orifice in fluid communication with the cavity for expelling the gas and a distribution disk for distributing the gas expelled through the outlet orifice and wherein a radius of the cavity is equal to or greater than a radius of the distribution disk.

In another embodiment, a system for conveying a glass sheet is described including a robot comprising a plurality of aero-mechanical devices to support and hold the glass sheet without contacting the sheet, each of the plurality of aero-mechanical devices comprising a body portion defining a cavity disposed therein, an inlet orifice and an outlet orifice in fluid communication with the cavity for respectively receiving and expelling a gas, and a distribution disk for distributing the expelled gas, a temperature control system for regulating a temperature of the gas emitted from the plurality of aero-mechanical devices, and wherein a radius of the cavity is equal to or greater than a radius of the distribution disk.

In still another embodiment, an apparatus for conveying a glass sheet is disclosed comprising a robot, a plurality of aero-mechanical devices connected to the robot, each of the plurality of aero-mechanical devices comprising a body portion defining a cavity disposed therein, an inlet orifice and an outlet orifice in fluid communication with the cavity for respectively receiving and expelling a gas, a distribution disk for distributing the expelled gas and a pickup surface, and wherein a diameter of the cavity is equal to or greater than a diameter of the distribution disk.

In another embodiment, a method of acquiring a glass sheet is described comprising providing a glass sheet having opposing first and second sides and an edge substantially perpendicular to the sides, moving an aero-mechanical device such that a pickup surface of the aero-mechanical device is at an index position proximate the first side of the glass sheet, and moving the pickup surface from the index position in a direction toward the first side of the glass sheet while simultaneously increasing a pressure of a gas supplied to the aero-mechanical device to acquire and hold the glass sheet without contacting the sheet.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate an exemplary embodiment of the invention and, together with the description, serve to explain the principles and operations of the invention.

### BRIEF DESCRIPTION OF THE DRAWINGS

FIG. 1 is a diagrammatic view of an exemplary glass manufacturing system using a glass handling system in accordance with an embodiment of the present invention.

FIG. 2A is a side view of a portion of the glass manufacturing system of FIG. 1 showing the traveling anvil machine (TAM).

FIG. 2B is a side view of a portion of the glass manufacturing system of FIG. 1 showing the conveyor.

FIG. 3A is a side cross sectional view of an aero-mechanical device according to an embodiment of the present invention.

FIG. 3B is a cross sectional view of a portion of the aero-mechanical device of FIG. 3A

FIG. 4 is a cross sectional view of another aero-mechanical device according to an embodiment of the present invention.

FIG. 5A is a cross sectional view of still another aero-mechanical device according to an embodiment of the present invention.

FIG. 5B is a cross sectional view of a portion of the aero-mechanical device of FIG. 5A.

FIG. 6A is a side view, in partial cross section, of a portion of the glass manufacturing system of FIG. 1 using yet another aero-mechanical device according to an embodiment of the present invention.

FIG. 6B is a cross sectional view of a portion of the glass manufacturing system of FIG. 1 showing a device for supporting at least a portion of the weight of the glass sheet by a contact method.

FIG. 6C is a cross sectional view of a portion of the glass manufacturing system of FIG. 1 showing another device for supporting at least a portion of the weight of the glass sheet by a non-contact method.

FIG. 7A is a front view of a portion of the glass manufacturing system of FIG. 1 showing the use of the aero-mechanical devices of FIG. 6A is a full-frame arrangement.

FIG. 7B is a front view of a portion of the glass manufacturing system of FIG. 1 showing the use of the aero-mechanical devices of FIG. 6A in a partial frame arrangement.

FIG. 8 is a diagrammatic view of a portion of the exemplary glass manufacturing system of FIG. 1 including a gas temperature control system.

FIG. 9 is a diagrammatic view of a portion of the exemplary glass manufacturing system of FIG. 1 including a gas flow control system.

FIG. 10 is a diagrammatic view of a portion of the exemplary glass manufacturing system of FIG. 1 including a position control system.

FIG. 11 is a plot comparing the vibration generated by a method wherein the desired final air pressure is applied to the aero-mechanical device before approaching the glass sheet, to the vibration generated by a method according to an embodiment of the present invention wherein the aero-mechanical device is brought to a pre-determined distance from the surface of the glass sheet, then pressure ramped up gradually as the aero-mechanical device is moved toward the surface of the glass sheet.

FIG. 12 is a superimposed side view of a conventional aero-mechanical device and an aero-mechanical device according to an embodiment of the present invention illustrating the various reference surfaces relative to FIGS. 13 and 14 below.

FIG. 13 is a plot showing the modeled velocity of air from a conventional aero-mechanical device, without a rounded lower edge, relative to the reference surfaces depicted in FIG. 12.

FIG. 14 is a plot showing the modeled velocity of air from an aero-mechanical device according to an embodiment of the present invention, with a rounded lower edge, relative to the reference surfaces depicted in FIG. 12.

FIG. 15 is a plot showing air pressure, as a function of radial distance from the central longitudinal axis of a conventional aero-mechanical device and an aero-mechanical device according to an embodiment of the present invention, between a reference surface (relative to FIG. 12) of the devices and an adjacent surface of a glass sheet.

### DETAILED DESCRIPTION

In the following detailed description, for purposes of explanation and not limitation, example embodiments disclosing specific details are set forth to provide a thorough understanding of the present invention. However, it will be apparent to one having ordinary skill in the art, having had the benefit of the present disclosure, that the present invention may be practiced in other embodiments that depart from the specific details disclosed herein. Moreover, descriptions of well-known devices, methods and materials may be omitted so as not to obscure the description of the present invention. Finally, wherever applicable, like reference numerals refer to like elements.

A fusion glass sheet forming process (e.g., downdraw process) forms high quality thin glass sheets that can be used in a variety of devices like flat panel displays. The fusion process is the preferred technique used today for producing glass sheets that are used in flat panel displays. Glass sheets formed by a fusion process have surfaces with superior flatness and smoothness when compared to glass sheets produced by other methods. A glass manufacturing system 100 that uses a fusion process to make a glass sheet is briefly described below, but for a more detailed description of the fusion process reference is made to U.S. Pat. Nos. 3,338,696 and 3,682,609. The contents of these two patents are incorporated herein by reference.

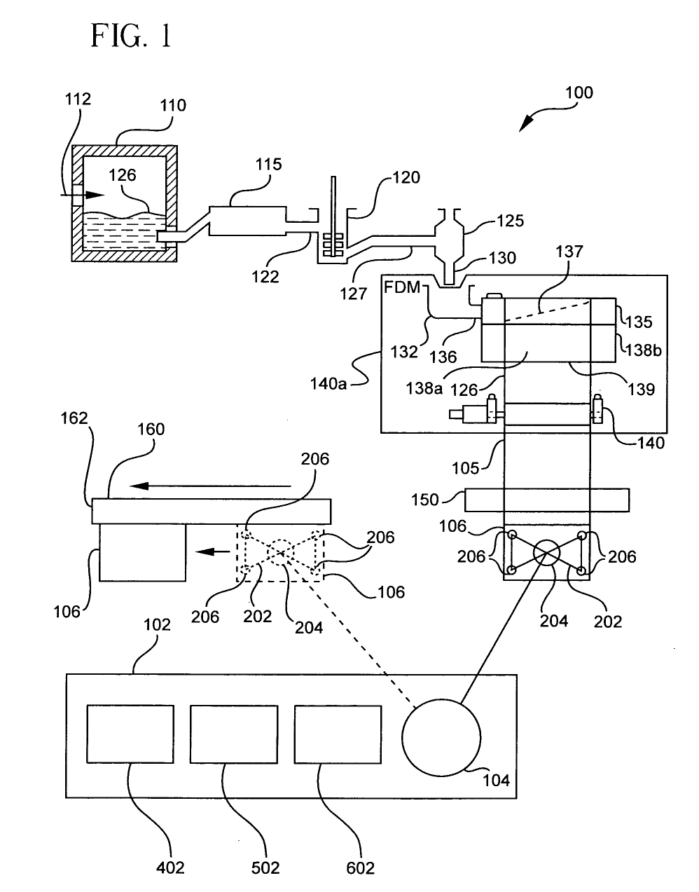

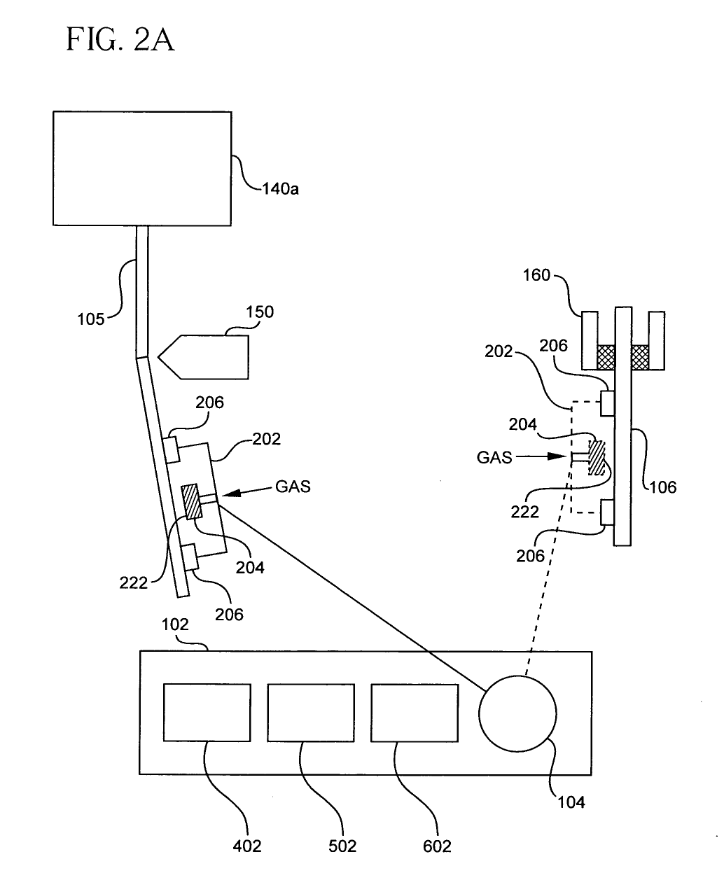

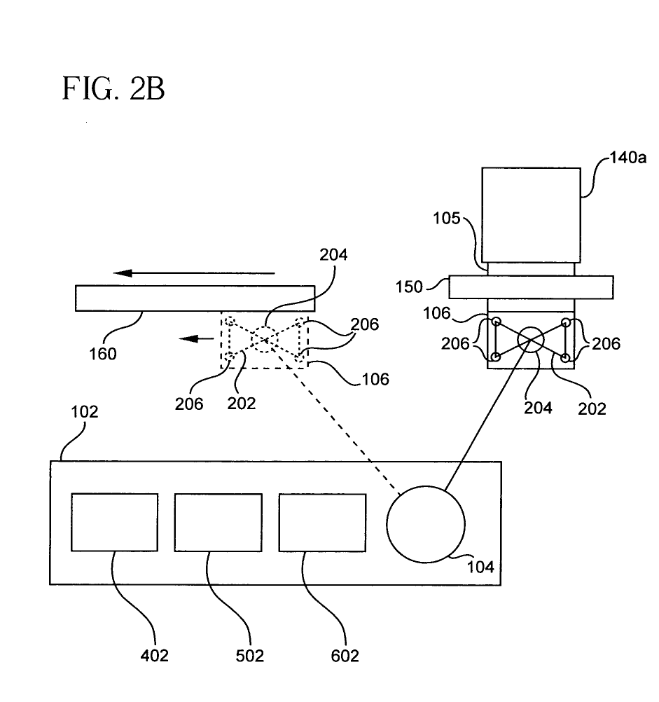

Referring to FIG. 1, there is shown a diagram of an exemplary glass manufacturing system 100 that uses the fusion process and glass handling system 102 of the present invention to make finished glass sheet 106. As shown, glass manufacturing system 100 includes melting vessel 110, fining vessel 115, mixing vessel 120 (e.g., stir chamber 120), delivery vessel 125 (e.g., bowl 125), fusion draw machine (FDM) 140a, traveling anvil machine (TAM) 150, conveyor 160 and glass handling system 102. Melting vessel 110 is where the glass batch materials are introduced, as shown by arrow 112, and melted to form molten glass 126. Fining vessel 115 (e.g., finer tube 115) has a high temperature processing area that receives molten glass 126 (not shown at this point) from melting vessel 110 and in which bubbles are removed from molten glass 126. Fining vessel 115 is connected to mixing vessel 120 (e.g., stir chamber 120) by finer to stir chamber connecting tube 122. Mixing vessel 120 is connected to delivery vessel 125 by stir chamber to bowl connecting tube 127. Delivery vessel 125 delivers molten glass 126 through downcorner 130 into FDM 140a which includes inlet 132, forming vessel 135 (e.g., isopipe 135), and pulling roll assembly 140. As shown, molten glass 126 from downcorner 130 flows into inlet 132 which leads to forming vessel 135. Forming vessel 135 includes opening 136 that receives molten glass 126 which flows into trough 137 and then overflows and runs down two opposing sides 138a and 138b of forming vessel 135 before fusing together at root 139. Root 139 is where the two opposing sides 138a and 138b of forming vessel 135 converge and where the two overflow walls of molten glass 126 rejoin (e.g., fuse) before being drawn downward by pulling roll assembly 140 to form glass sheet 105. TAM 150 cuts drawn glass sheet 105 into distinct pieces of glass sheet 106. At this point, the glass sheet 106 is hot—significantly above room temperature. Glass handling system 102, and in particular enhanced robot 104, then acquires cut glass sheet 106 and moves glass sheet 106 from TAM 150 to conveyor 160 which is located in a Bottom of the Draw (BOD) area. This area is referred to as the Hot BOD (HBOD), as glass sheet 106 is still hot. Conveyor 160 then conveys glass sheet 106, which cools along the way, through a couple of process steps. At end 162 of conveyor 160, which is referred to as the Cold End, glass sheet 106 is packaged along with other glass sheets 106 so they can be sent to customers. A detailed discussion of the operation and different components of the glass handling system 102 and enhanced robot 104 is provided below with respect to FIGS. 2A-2B.

Referring to FIGS. 2A and 2B, there are shown side views of portions of glass manufacturing system 100 shown in FIG. 1 which are used to help explain how enhanced robot 104 acquires and moves cut glass sheet 106 from TAM 150 to conveyor 160. As shown, enhanced robot 104 includes a frame 202 and one or more aero-mechanical devices 204 connected to frame 202 to couple to and hold glass sheet 106 and then move glass sheet 106 from TAM 150 to conveyor 160. In one embodiment, additional aero-mechanical devices 206 contact and support the outer edges or non-quality area of the glass sheet 106. The one or more aero-mechanical devices 204 receive gas from a gas supply unit (not shown) and emit gas toward the center portion or quality area of glass sheet 106 in a manner that enables the one or more aero-mechanical devices 204 to support and hold the center portion of glass sheet 106 without contacting the center, quality area of glass sheet 106 while glass sheet 106 is moved from TAM 150 to conveyor 160. In the embodiment illustrated in FIGS. 1-2, additional aero-mechanical devices 206 may be employed such that the additional devices 206 contact and support the outer edges or non-quality area of glass sheet 106. A description as to how the one or more aero-mechanical devices 204 are able to acquire and hold the quality area of glass sheet 106 without contacting the quality area of glass sheet 106 is provided below.

Aero-mechanical device 204 is configured such that gas from the gas supply unit flows through device 204 in a manner that creates a gas film on one side of glass sheet 106 such that if glass sheet 106 moves too far away from a face or pickup surface of aero-mechanical device 204 then a suction force (Bernoulli suction force) created by gas emitted from aero-mechanical device 204 pulls glass sheet 106 back to aero-mechanical device 206. And, if glass sheet 106 moves too close to a pickup surface of aero-mechanical device 204 then a repulsive force caused by the gas emitted from aero-mechanical device 204 pushes glass sheet 106 away from aero-mechanical device 204. It is the balance between the suction force and the repulsion force that enables aero-mechanical device 204 to hold glass sheet 106 from a single side at a given position without having to touch glass sheet 106.

Prior art aero-mechanical devices have not provided the holding force needed to acquire and securely hold very large sheets of glass, for example glass sheets that approach or exceed 10 square meters, particularly aero-mechanical devices which operate on the Bernoulli principal. Conventional Bernoulli aero-mechanical devices tend to have a squared-off edge on the pickup surface (the surface of the aero-mechanical device closest to the glass sheet, and incorporate narrow gas distribution passages within the device. In the first instance, a squared-off edge may damage glass sheets with inadvertent contact. This is particularly true when the fly height (the distance between the closest point of the pickup surface and the substrate being acquired) is very small (typically less than about 100 μm) and the pickup surface is not substantially parallel with a plane of the pickup surface, remembering that for the still-hot glass ribbon descending from the isopipe, the ribbon or sheet generally has a width-wise curvature. This may occur, for example, as the aero-mechanical device 204 is engaging or disengaging with the glass sheet 106. It has been found that with conventional devices having as little as a 2° angular offset between the surface of the glass sheet and the proximal chuck surface, an edge of the conventional Bernoulli chuck can contact the sheet prior to the chuck stabilizing itself and forming the proper fly height. In the second instance, it has been found that the abrupt (e.g. sharp) edge at the outer circumference of the pickup surface results in a reduced holding force on the substrate.

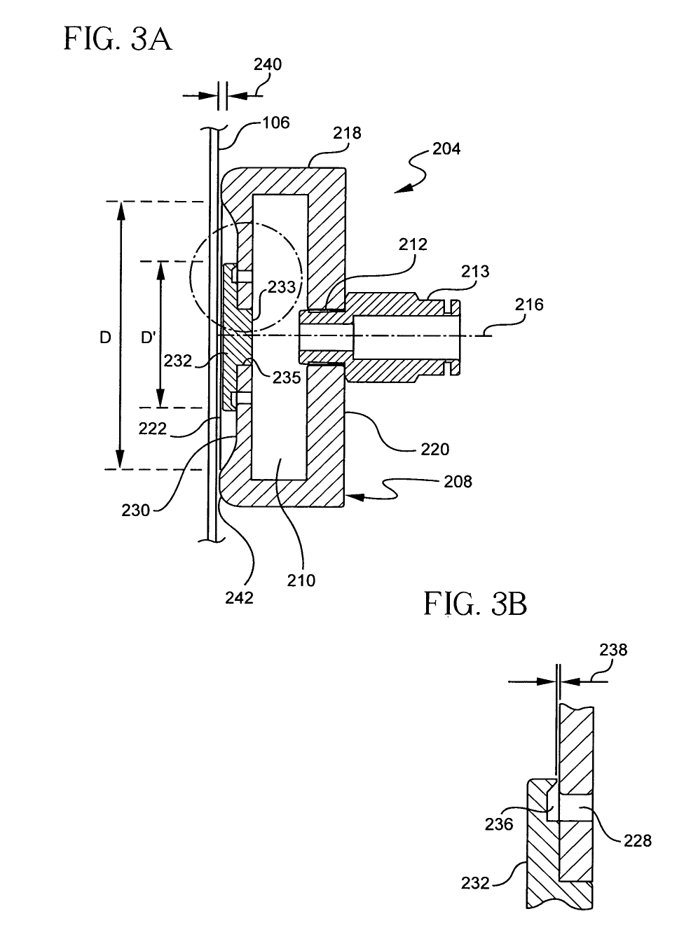

Shown in FIGS. 3A-3B is an exemplary aero-mechanical device 204 according to an embodiment of the present invention. Aero-mechanical device 204 comprises body portion 208 defining a cavity 210 interior to the body portion and at least one inlet port 212 for receiving a supply of pressurized gas from the gas supply unit through fitting 213. Preferably, the pressurized gas is clean, dry air. That is, the pressurized gas should be filtered and free of moisture and/or oil. It will hereinafter be assumed, for purposes of description and not limitation, that the pressurized gas supplied to cavity 210 is air. Since the supplied gas continuously issues from aero-mechanical device 204 during use, air serves as an inexpensive, non-polluting working fluid.

Body portion 208 is preferably cylindrical in character and comprises a longitudinal axis 216 and an outside surface 218 concentric with longitudinal axis 216. Body portion 208 also includes a top surface 220 and a bottom or pickup surface 222. Inlet port 212 is in fluid communication with cavity 210. Fitting 213 may be any suitable conventional fitting for connecting to a gas supply line (not shown). In some embodiments, inlet port 212 is concentric with longitudinal axis 216 of the body portion. As best seen in FIG. 3B illustrating the circled detail in FIG. 3A, at least one outlet port 228 is also in fluid communication with cavity 210. Pickup surface 222 is preferably non-planar, and as illustrated in FIG. 3A, comprises a central depression 230.

In accordance with the present embodiment, aero-mechanical device 204 further comprises a flow guide or distribution disk 232 centrally disposed within depression 230. Distribution disk 232 is generally circular in shape with a central axis coincident with longitudinal axis 216, and may be attached to body portion 208 by pressing a portion of the disk structure into an appropriate mating structure within the body portion. For example, distribution disk 232 may comprise a cylindrical pedestal 233 on a surface thereof which is pressed into a suitably shaped opening 235 in body portion 208. The fit should be sufficiently tight to hold distribution disk 232 to body portion 208 during operation of the aero-mechanical device 204.

Distribution disk 232 further comprises a groove or distribution channel 236 for distributing pressurized air received from cavity 210 through the at least one outlet port 228. Preferably distribution channel 236 is disposed in an “upper” surface of the disk, adjacent body portion 208 in the assembled aero-mechanical device 204, as seen in FIG. 3B. Thus, the at least one outlet port 228 connects cavity 210 with distribution channel 236. Pressurized gas (e.g. air) from cavity 210 is fed by outlet port 228 into distribution channel 236, where the air thereafter circulates through and out of distribution channel 236 from a narrow gap 238 between distribution disk 236 and pickup surface 222 into depression 230. Output port 228 may be a single opening in body portion 208 concentric with longitudinal axis 216. However, body portion 208 may comprise a plurality of discrete outlet ports 228 such that distribution channel 236 may be provided with pressurized gas from a number of locations around the circumference of the distribution channel. In some embodiments, outlet port 228 would be a single annular port concentric with axis 216. If a plurality of outlet ports are used, the outlet ports may, for example, be distributed equally about longitudinal axis 216. For example, the plurality of outlet ports 228 may be configured at equal angular spacing about longitudinal axis 216, such as, for example, every 30 degrees, and be equidistant from longitudinal axis 216. However, it is not required that the angular spacing be equal, or that a plurality of gas outlet ports be equidistant from axis 216.

As the supplied gas flows through a small gap 240 between glass sheet 106 and pickup surface 222 of aero-mechanical device 204, it flows faster, increasing the dynamic pressure ρU² where ρ is the gas density and U is the gas velocity. The increase in the dynamic pressure ρU² means that the static pressure P is reduced in accordance with the Bernoulli equation which states P+ρU²=0. It is this reduction in static pressure P which generates a negative pressure or vacuum by which aero-mechanical device 204 can hold glass sheet 106.

To ensure a substantially uniform flow of air from distribution channel 236 into depression 230, it is desirable for cavity 210 to have a large volume. That is, cavity 210 should serve as an accumulator to prevent surging of the air flow into distribution channel 236. In accordance with some embodiments, cavity 210 is cylindrical in shape with a longitudinal axis coincident with longitudinal axis 216 such that cavity 230 and body portion 208 share common longitudinal axis 216. Moreover, longitudinal axis 216 is coincident with the center of distribution disk 232, such that body portion 208 and disk 232 share common longitudinal axis 216. Longitudinal axis 216 will hereinafter be interpreted to be the central axis for each of body portion 208, cavity 210 and distribution disk 232. The maximum diameter D of cavity 210 should be at least as large as the maximum diameter D′ of distribution disk 232, and the diameter of cavity 210 is preferably larger than the diameter of distribution disk 232.

It has been found that the larger the diameter of distribution disk 232, the greater the holding force that can be obtained. Preferably, the diameter D′ of distribution disk 232 is at least about 13 mm, more preferably at least about 15 mm.

It has also been found that an increase in holding force can be obtained if the lower portion of body 208 has a rounded edge. That is, a circumferential edge 242 of body 208 is preferably rounded so that outer surface 218 flows or blends smoothly into pickup surface 222 with no sharp edges. For example, in one embodiment edge 242 includes a radius of curvature of about 0.3 cm. It is believed that rounded edge 242 stabilizes the flow of air between the surface of glass sheet 106 captured by the aero-mechanical device and pickup surface 222, thereby helping to make the flow substantially uniform in velocity and pressure. This in turn increases the holding ability of the aero-mechanical device. Additionally, rounded edge 242 also helps prevent contact with the target object if the aero-mechanical device is tilted or skewed as it approaches the object. For example, if the aero-mechanical device is brought into the proximity of the glass sheet such that pickup surface 222 is generally non-parallel or tilted relative to the glass sheet (or vice versa), there is a danger that an edge of the aero-mechanical device may contact and damage the glass sheet. Rounded edge 242 minimizes the risk of contact between the aero-mechanical device and the target object.

Modeling results have shown that by incorporating a rounded edge, the velocity of air exiting the interfacial region 240 between the pickup surface and glass sheet 106 is reduced when compared to an identical aero-mechanical device with an abrupt edge, that is, wherein the intersection between surface 218 and pickup surface 222 is substantially at 90 degrees. It has been found that when air exits interfacial gap 240 at high velocity, the air becomes turbulent near an abrupt edge, contributing to vibration of the glass sheet. Additionally, there is greater resistance to the flow of air exiting interfacial gap 240 when an abrupt edge is present, which leads to a reduction in the holding (e.g. lifting) force of aero-mechanical device 204.

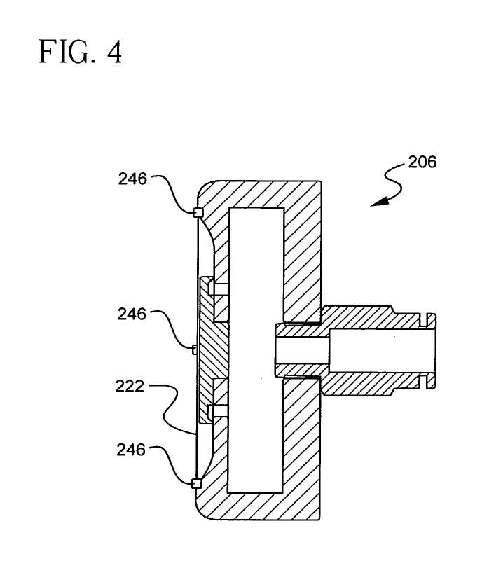

Aero-mechanical devices 206 may be similar in construction to aero-mechanical devices 204, but may further comprise standoffs 246 (FIG. 4) disposed in or on pickup surface 222 such that glass sheet 106 is held a pre-determined distance from pickup surface 222. Standoffs 246 also provide a lateral friction force against the sheet to prevent lateral movement of the sheet is the sheet is non-horizontal. For example, standoffs 246 may be rubber “feet” that are inserted into suitable holes in pickup surface 222 such that the feet extend a pre-determined distance from pickup surface 222. A cross sectional view of an aero-mechanical device 206 is shown in FIG. 4. It is preferable that standoffs 246 comprise a resilient material that is softer than the glass sheet so that the surface of the glass sheet 106 is not damaged by contact with the standoffs. It is also desirable that the distance each of the standoffs extends above pickup surface 222 is such that the force exerted on glass sheet 106 by the air issuing from aero-mechanical device 204 does not exceed the force exerted on the glass sheet by the ambient atmosphere so that the glass sheet is forced against the standoffs and held securely. Alternatively, an edge clamp that contacts the non-quality edges of the glass sheet may be used to prevent lateral movement of the sheet.

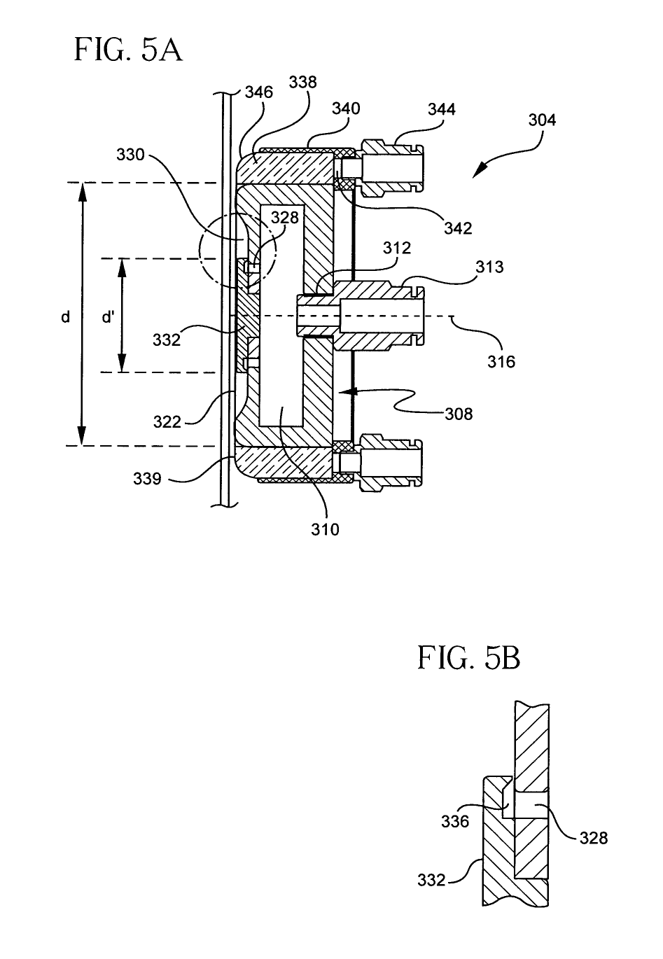

In another embodiment illustrated in FIGS. 5A-5B, the at least one aero-mechanical device 304 may be substituted for aero-mechanical device 204. Aero-mechanical device 304 comprises body portion 308 defining cavity 310 interior to the body and at least one inlet port 312 for receiving a supply of pressurized gas from a source (not shown). Body portion 308 preferably comprises a longitudinal axis 316 and a bottom or pickup surface 322. Inlet port 312 is in fluid communication with cavity 310, and may be equipped with any suitable conventional fitting 313 for connecting to the pressurized fluid supply line. Preferably, inlet port 312 is concentric with longitudinal axis 316 of the body portion.

At least one outlet port 328 is also in fluid communication with cavity 310. Preferably, the pressurized gas is clean, dry air, and is received into cavity 310 through inlet port 312. That is, the pressurized gas should be filtered and free of moisture and/or oil. Since the pressurized gas continuously issues from aero-mechanical device 304 during use, air serves as an inexpensive, non-polluting working fluid.

In accordance with the present embodiment, pickup surface 322 is preferably non-planar, and as illustrated in FIG. 5A, comprises a central depression 330. Aero-mechanical device 304 further comprises a distribution disk 332 centrally disposed within depression 330. Distribution disk 332 is generally circular in shape with a central axis coincident with longitudinal axis 316, and may be attached to body portion 308 by pressing a portion of the disk structure into an appropriate mating structure within the body portion. For example, distribution disk 332 may comprise a cylindrical pedestal on an upper surface thereof which is pressed into a suitably shaped depression in body portion 334. The fit should be sufficiently tight to hold distribution disk 332 to body portion 308.

Distribution disk 332 further comprises a groove or distribution channel 336 for distributing pressurized air from cavity 210, as best seen in FIG. 5B. Preferably the distribution channel is disposed in an “upper” surface of the disk, adjacent body portion 308 in the assembled aero-mechanical device 304. Thus, the at least one outlet port 328 connects cavity 310 with distribution channel 336. Pressurized air from cavity 310 is fed by outlet port 328 into distribution channel 336, where the air thereafter circulates through and out of distribution channel 336 from between distribution disk 332 and pickup surface 322 and into depression 330. In some embodiments, output port 328 may be a single annular opening in body portion 308 concentric with longitudinal axis 316. However, body portion 308 may comprise a plurality of discrete outlet ports 328 such that distribution channel 336 may be provided with pressurized air from a number of locations around the circumference of the distribution channel. The outlet ports may, for example, be distributed equally about longitudinal axis 316. For example, the plurality of outlet ports 328 may be configured at equal angular spacing about longitudinal axis 316.

To ensure a substantially uniform flow of air from distribution channel 336 into depression 330, it is desirable for cavity 310 to have a large volume. That is, cavity 310 should serve as an accumulator to prevent surging of the air flow into distribution channel 336. In accordance with some embodiments, cavity 310 is cylindrical in shape with a longitudinal axis coincident with longitudinal axis 316 such that cavity 310 and body portion 308 share a common longitudinal axis. Moreover, longitudinal axis 316 is coincident with the center of distribution disk 332, such that body portion 308 and disk 332 share a common longitudinal axis. Longitudinal axis 316 will hereinafter be interpreted to be the central axis for each of body portion 308, cavity 310 and distribution disk 332. The maximum diameter d of cavity 210 should be at least as large as the maximum diameter d′ of distribution disk 332, and the diameter d of cavity 310 is preferably larger than the diameter d′ of distribution disk 332.

In accordance with the present embodiment, aero-mechanical device 304 may further comprise an annular-shaped porous material 338 disposed about a circumference of body portion 308, and enclosure 340 disposed about a portion of porous material 338. Porous material 338 may comprise any suitable material capable of providing a distributed outflow of air about a circumference of body portion 308, but particularly through a bottom surface 339 of porous material 338. For example, porous material 338 may comprise graphite, or be a porous sintered metal such as sintered bronze. Alternatively, porous material 338 may instead comprise an annular disk defining a plurality of outlets for air to exit through. The number of outlets may number in the hundreds to ensure an even distribution of air.

Enclosure 340 includes at least one opening or port 342 into which a fitting 344 is attached for receiving a supply of pressurized air, and is adapted such that bottom surface or face 339 of porous material 338 remains exposed (i.e. uncovered by enclosure 340). Thus, pressurized air introduced into enclosure 340 through fitting 344 may escape through exposed face 339 of porous material 338. In a preferred embodiment, enclosure 340 includes several inlet ports, as shown in FIG. 5A, to ensure a more uniform air supply to the porous material.

Pressurized air issuing from exposed face 339 of porous material 338 provides a force against glass sheet 106 to help ensure that glass sheet 106 is not contacted by edges of the porous material. This may occur, for example, if the aero-mechanical device is tilted with respect to the plane of the glass sheet. Additionally, an outside edge 346 of porous material 338 may be rounded in a manner similar to the previous embodiment to further ensure that an edge of the aero-mechanical device does not contact the glass sheet. As in the previous embodiment, FIG. 5B illustrates the circled detail in FIG. 5A, and in particular the structure around disk 332.

It should be appreciated that there are other configurations that the aero-mechanical device can have besides the configuration shown in FIGS. 3A, 3B and 5A, 5B (i.e. devices 204, 304). For example, the one or more aero-mechanical devices can be of the flat panel type comprising both pressure ports and vacuum ports, such as flat panel aero-mechanical devices sold by New Way® Air Bearings. Indeed, if flat panel aero-mechanical devices are used, they may be used to flatten glass sheet 106 in the region proximate the device. For example, the flat panel aero-mechanical device may be employed to hold and flatten glass sheet 106 proximate the score line to improve the quality of the score, and the subsequent separation of the glass sheet. Flattening of the glass sheet during the scoring and separating operation through the use of such panel-sized aero-mechanical devices can be effective to improve these processes as the size of glass sheets become larger.

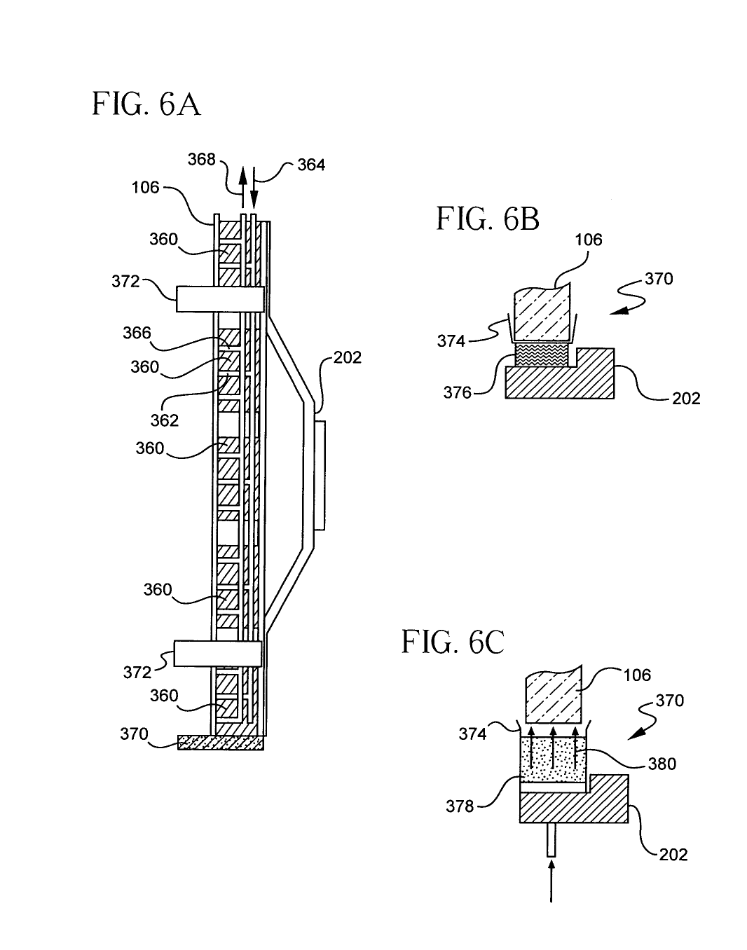

Accordingly, FIG. 6A illustrates a plurality of flat panel aero-mechanical devices 360 of the New Wave type. Such aero-mechanical devices typically include a substantially planar pickup surface comprising both pressure ports 362 for receiving a pressurized gas from a gas supply source as indicated by arrow 364, and vacuum ports 366 to which a vacuum is applied by a vacuum source as indicated by arrow 368. The vacuum ports exert a holding force, while the pressure ports expel a gas toward a surface of the glass sheet, thus exerting a repelling force. By balancing the holding and repelling forces, the glass sheet may be held at a predetermined position away from the surface of the aero-mechanical device. As depicted in FIG. 6A, frame 202 includes a plurality of aero-mechanical devices 360 attached thereto, a support member 370 for supporting at least a portion of the weight of glass sheet 106, and tabs 372 for constraining lateral movement of glass sheet 106 and for providing a guiding function during acquisition of the glass sheet by the at least one aero-mechanical device 360. Advantageously, the plurality of aero-mechanical devices 360 may be supplied with different gas pressures and/or different amounts of vacuum to vary the fly-height of glass sheet 106. For example, glass sheets drawn from a fusion downdraw device typically include thickened edge portions, therefore, it would be desirable to be able to adjust the fly height of the glass sheet to accommodate these thickened areas.

Tabs 372 are preferably deformable or flexible (e.g. resilient), and may be formed, for example, from a natural or synthetic rubber. Alternatively, tabs 372 may be rigid but movable, such as being hinged and spring loaded.

Support member 370 may, for example, comprise a grooved or channeled member 374 supported by a resilient or flexible member 376 attached to frame 202 as depicted by FIG. 6B. Member 376 may, for example, comprise a spring. At least a portion of the weight of glass sheet 106 is then supported by physical contact with channel member 374. Alternatively, support member 370 may comprise a porous material 378 supplied with a pressurized gas for supporting glass sheet 106 via an edge of glass sheet 106, as illustrated in FIG. 6C. Pressurized gas issuing from porous material 378 (depicted by arrows 380) levitates glass sheet 106, providing contactless weight support for glass sheet 106.

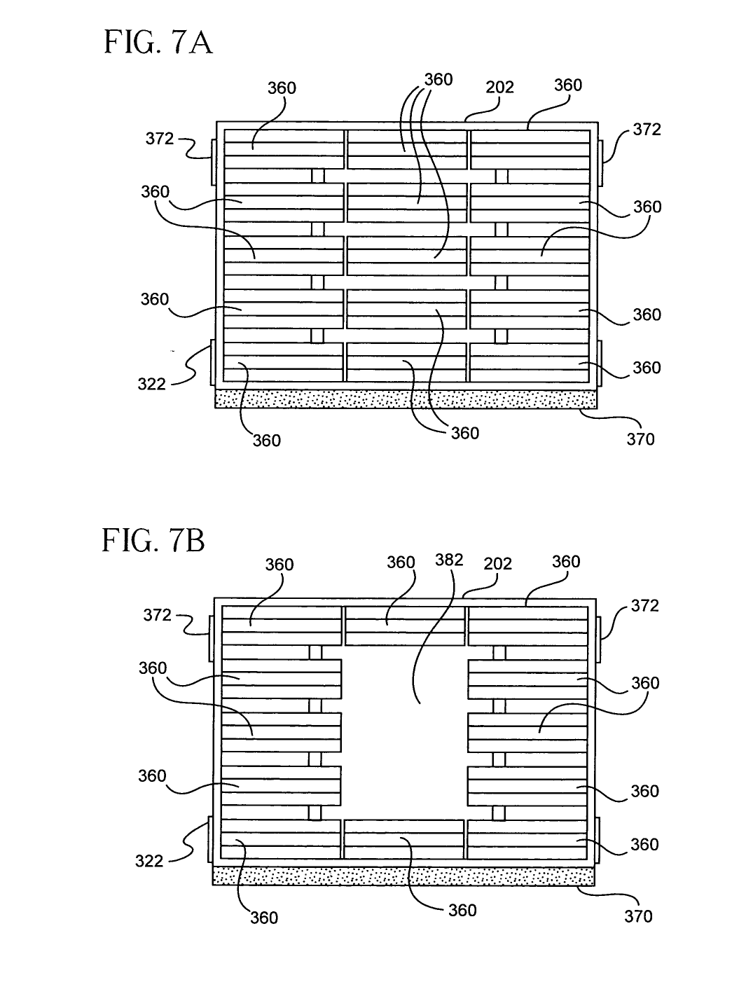

Aero-mechanical devices 360 may be “full frame” in the sense that the aero-mechanical devices span substantially the full surface area of a side of glass sheet 106, as shown in FIG. 7A, or aero-mechanical devices 360 may be arranged in a partial frame such that they support and stiffen an outer area of the glass sheet while leaving a central portion of glass sheet 106 unsupported, as depicted in FIG. 7B. The arrangement of FIG. 7B shows a plurality of aero-mechanical devices 360 positioned in a frame-like arrangement with a central portion 382 of the arrangement free of aero-mechanical devices. The frame-like arrangement can reduce the weight of the apparatus that must be supported by robot 104.

To assist enhanced robot 104, and in particular aero-mechanical device 204 (and/or 206, 304 or 360), in handling glass sheet 106, the gas exiting the aero-mechanical devices can be heated to match the temperature of glass sheet 106, which cools as it is moved from TAM 150 to conveyor 160, to avoid the creation of a temporary warp in glass sheet 106. This is particularly true for glass sheets 106 of non-uniform thickness such as those with beads along the vertical edges as typically produced by fusion draw machine 140a. Experiments have indicated that a significant amount of warp in glass sheet 106 can be thermally induced when the temperature of the gas exiting the aero-mechanical devices does not match the temperature of glass sheet 106. To simplify further discussion, the following description will be presented in terms of aero-mechanical device 204 and/or 206, with the understanding that the disclosed features may be used with the other aero-mechanical devices described herein.

Temporary warp can dramatically reduce the effectiveness of aero-mechanical device 204. Thermally induced warp in glass sheet 106 may also alter the interaction between the additional aero-mechanical devices 206 and glass sheet 106. In addition, thermally induced warp in glass sheet 106 may create stress which could cause a crack to propagate within cut glass sheet 106. This crack could originate from a flaw along one of the edges of sheet 106 or from any flaws within the body of glass sheet 106. In addition, thermally induced stress due to temperature gradients within glass sheet 106 may cause a crack to propagate through cut glass sheet 106.

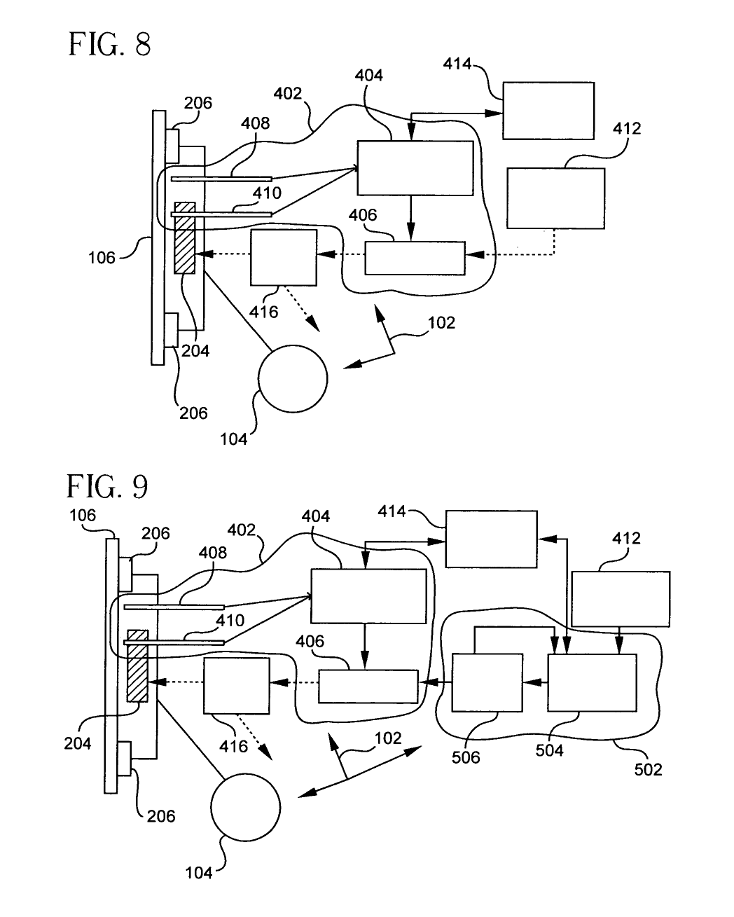

To address this concern, glass handling system 102 may include a temperature control system 402 (FIG. 8) that can regulate the temperature of the gas emitted from aero-mechanical device 206 towards glass sheet 106 such that the temperature of the gas emitted from aero-mechanical device 206 substantially matches the current temperature of glass sheet 106. Again, it should be noted that glass sheet 106 constantly cools as it is moved by enhanced robot 104 from TAM 150 to conveyor 160. As such, temperature control system 402 needs to constantly reduce the temperature of the gas that is emitted from aero-mechanical device 204 to match the temperature of moving glass sheet 106. A detailed discussion as to how temperature control system 402 can regulate the temperature of the gas emitted from aero-mechanical device 204 is provided below with respect to FIG. 8.

Referring to FIG. 8, there is a block diagram illustrating the basic components of an embodiment of glass handling system 102 which includes enhanced robot 104 and temperature control system 402. As shown, temperature control system 402 includes a temperature controller 404, gas heater 406 and two temperature measuring devices 408 and 410. The first temperature measuring device 408 measures a temperature of glass sheet 106. And, the second temperature measuring device 410 measures a temperature of glass sheet 106 at a location substantially identical to the area impinged upon by gas emitted from aero-mechanical device 204. Alternatively, the second temperature measuring device 410 can measure a temperature of the gas emitted from aero-mechanical device 204. Temperature controller 404 receives the measured temperatures from both of temperature measuring devices 408 and 410 and then controls a set-point on gas heater 406 to heat the gas received from gas supply unit 412 such that the temperature of the gas emitted from aero-mechanical device 204 is the same as or a little more or a little less than the current temperature of glass sheet 106, e.g. substantially matches. In practice, the temperature of the gas emitted from aero-mechanical device 204 may be somewhat less than the current temperature of glass sheet 106 so as to equal the cooling provided by natural convection to the remainder of glass sheet 106. Another purpose of temperature control system 402 can be to help constrain the motion of glass sheet 106 during the acquisition period with enhanced robot 104.

In one embodiment, first and second temperature measuring devices 408 and 410 are located on the same side of glass sheet 106 as the one or more aero-mechanical devices 204. First temperature measuring device 408 should not contact glass sheet 106 and should be located in an area not affected by the gas emitted from aero-mechanical device 204. And, the second temperature measuring device 410 should not contact glass sheet 106 and should be located in an area that is affected by the gas emitted from aero-mechanical device 204. Of course, the temperature measurement of the thermal impact of aero-mechanical device 204 (gas temperature exiting air device or glass temperature) should be precise. Assuming, the gas exit temperature is used as the feedback metric, it will need to be “calibrated” to the temperature of the glass sheet 106 to properly program the temperature controller 104.

Gas heater 406 may be selected to be capable of altering the gas temperature exiting aero-mechanical device 204 to nearly instantaneously match the current temperature of glass sheet 106. This means that gas heater 406 should have a low thermal inertia and relatively low response time as the temperature of the glass sheet 106 can drop very fast. Of course, gas heater 406 should not generate or transport particulates or other contaminants to the surface of glass sheet 106.

A central computer 414 (optional) is also shown in FIG. 8 that can be used to help control temperature controller 404 and can also be used to help control the operation of an optional three-way valve 416. Three-way valve 416 can be controlled to permit the gas emitted from gas heater 406 to enter or bypass aero-mechanical device 204. Three-way valve 416 would be configured to bypass or prevent the gas from entering aero-mechanical device 204 when glass sheets 106 are not being produced so as to reduce the effect upon the environment near TAM 150. Three-way valve 416 can also be configured to bypass or prevent the gas from entering aero-mechanical device 204 when device 204 approaches drawn glass sheet 105 below TAM 150 as well as when device 204 releases cut glass sheet 106 to the conveyor. Alternatively, three-way valve 416 can be manually operated.

Referring to FIG. 9 there is a block diagram illustrating the basic components of another embodiment of glass handling system 102 that includes a flow control system 502 in addition to enhanced robot 104 and temperature control system 402. As shown, flow control system 502 includes a flow controller 504 and a flow sensor 506 that function together to control the flow rate of the gas emitted from aero-mechanical device 204, and optionally 206. Flow control system 502 is helpful in several ways. First, it can be utilized when enhanced robot 104 acquires glass sheet 106 and when it disengages from glass sheet 106. During the acquisition process, flow controller 504 can gradually increase the flow of gas to aero-mechanical devices 204, 206 to move glass sheet 106 smoothly toward aero-mechanical devices 204, 206. During disengagement, flow controller 504 can gradually decrease the flow of gas to aero-mechanical devices 204, 206 to move glass sheet 106 smoothly away from the aero-mechanical devices. This type of flow control may be preferable since if one merely cycles the gas to aero-mechanical devices 204, 206 on and off, then glass sheet 106 could move rapidly towards the aeromechanical devices 204, 206 and produce contact damage and/or excess vibration. Secondly, control of the gas flow could also be used to fine tune the position of glass sheet 106 relative to aero-mechanical devices 204, 206. Central computer 414 can be used to control the operation of flow controller 504.

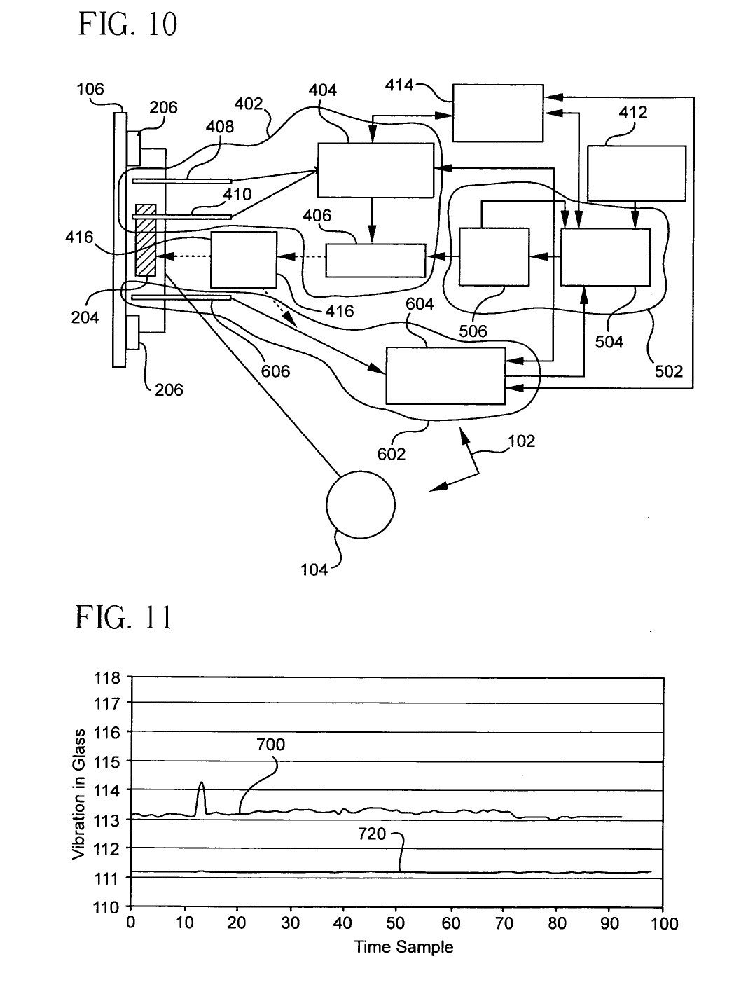

Referring to FIG. 10, there is a block diagram illustrating the basic components of a third embodiment of the glass handling system 102 that includes a position control system 602 in addition to enhanced robot 104, temperature control system 402 and flow control system 502. As shown, position control system 602 includes a position controller 604 and a position sensor 606 that function together to control the flow rate and/or temperature of the gas emitted from aero-mechanical devices 204, 206 so as to control the position of glass sheet 106 relative to aero-mechanical devices 204, 206, or the position of the aero-mechanical devices to glass sheet 106 according to pre-determined instructions. In operation, position control sensor 604 receives a signal from position sensor 606 that indicates the position of glass sheet 106 and then sends one or more control signals to flow controller 502 and/or temperature controller 402 to control and change the position of glass sheet 106 relative to aero-mechanical devices 204, 206 or the position of the aero-mechanical devices, via robot 104, to glass sheet 106 according to pre-determined instructions. In this way, position controller 604 can control the magnitude of the gap between glass sheet 106 and aero-mechanical devices 204, 206. Central computer 414 can be used to control the operation of position controller 604.

This method of controlling the position of glass sheet 106 can be used to improve the ability of robot 104 to acquire and move glass sheet 106. In particular, sheet position controller 604 can be used to control the force produced by aero-mechanical devices 204 and/or, 206 to hold glass sheet 106 in a fixed position with respect to face 222 of aero-mechanical device 204 and/or 206 while taking into account changes in the load in a direction normal to moving glass sheet 106. This load includes the gravitational force that is applied when enhanced robot 104 moves and tilts glass sheet 106 through a variety of angles. This load also includes the aerodynamic drag that is created when enhanced robot 104 moves and tilts glass sheet 106 through ambient air at varying speeds.

The basic steps of a preferred method for engaging and moving glass sheet 106 in accordance with embodiments of the present invention begin with enhanced robot 104 engaging and moving glass sheet 106 using at least one aero-mechanical device 204 (or 304 or 360) that supports and holds the glass sheet 106 without contacting the glass sheet 106.

Temperature control system 402 can be used to regulate a temperature of the gas emitted from aero-mechanical device 204 towards glass sheet 106 such that the temperature of the gas emitted from aero-mechanical device 204 substantially matches a temperature of glass sheet 106. A detailed discussion about exemplary temperature control system 402 was described above with respect to FIG. 8.

Flow control system 502 can be used to control the flow rate of the gas emitted from aero-mechanical device 204 so aero-mechanical device 204 can effectively acquire glass sheet 106 and disengage from glass sheet 106. A detailed discussion about exemplary flow control system 502 was described above with respect to FIG. 9.

Position control system 602 can be used to control a flow rate and/or temperature of the gas emitted from aero-mechanical device 204 so as to control a position of glass sheet 106 relative to aero-mechanical device 204 (e.g. robot 104), or alternatively, to control the position of aero-mechanical device 204 (e.g. robot 104) relative to a position of glass sheer 106. A detailed discussion about position control system 602 was described above with respect to FIG. 10. For example, position control system 602 and flow control system 502 may work together so that the gas pressure delivered to aero-mechanical device 204 is ramped up (or down) as aero-mechanical device 204 moves toward (or away from) glass sheet 106. Thus, aero-mechanical device 204 can smoothly acquire (or disengage) with glass sheet 106 and minimize vibration of the sheet. Minimizing vibration is a very desirable attribute of a conveyance system that is used during glass sheet separation at the bottom of the draw area. Vibration of the sheet during engagement of the robot 104 (and aero-mechanical device 204) and prior to separation of the sheet can propagate upward into the viscous region of the glass and negatively impact the shape of the sheet. Consequently, minimal vibration is a valuable advantage. In one embodiment, robot 104 positions aero-mechanical device 204 in a range from about 1 mm to about 5 mm from the surface of glass sheet 106. Robot 104 then moves aero-mechanical device 204 toward glass sheet 204 while flow control system 502 and position control system 602 coordinate, such as through central computer 414, to increase the gas pressure supplied to aero-mechanical device 204 until the supplied pressure is appropriate for the desired working distance (fly height), as determined by position control system 602.

### EXAMPLE 1

In one experiment, illustrated in FIG. 11, aero-mechanical device 204 was brought into position by robot 104 at a distance in excess of 5 mm from the surface of glass sheet 106. The pressure to aero-mechanical device 204 was increased to the desired working pressure, and aero-mechanical device 204 then brought to the appropriate fly height above the surface of glass sheet 106. That is, the aero-mechanical device had reached an appropriate working pressure prior to arriving at the desired fly height. Curve 700 depicts a plot of displacement (vibration) as a function of time for this instance. The experiment was repeated, except that the pressure supplied to aero-mechanical device 204 was first brought to within about 3 mm of the surface of the glass sheet before beginning a ramp (increase) of the pressure to the desired working pressure. A similar plot of displacement vs. time is depicted by curve 702. Curve 702 illustrates a marked reduction in vibration.

From the foregoing, it can be readily appreciated by those skilled in the art that glass handling system 102 that utlizes enhanced robot 104 and aero-mechanical devices 204 and aero-mechanical devices 206 to acquire and move glass sheet 106 is a marked improvement over the traditional robot that simply used suction cups to acquire and move glass sheet 106. This improvement is possible because enhanced robot 104 is able to acquire and hold the center portion of glass sheet 106 as well as the outer edges of glass sheet 106, whereas the traditional robot can only acquire and hold the outer edges of glass sheet 106.

### EXAMPLE 2

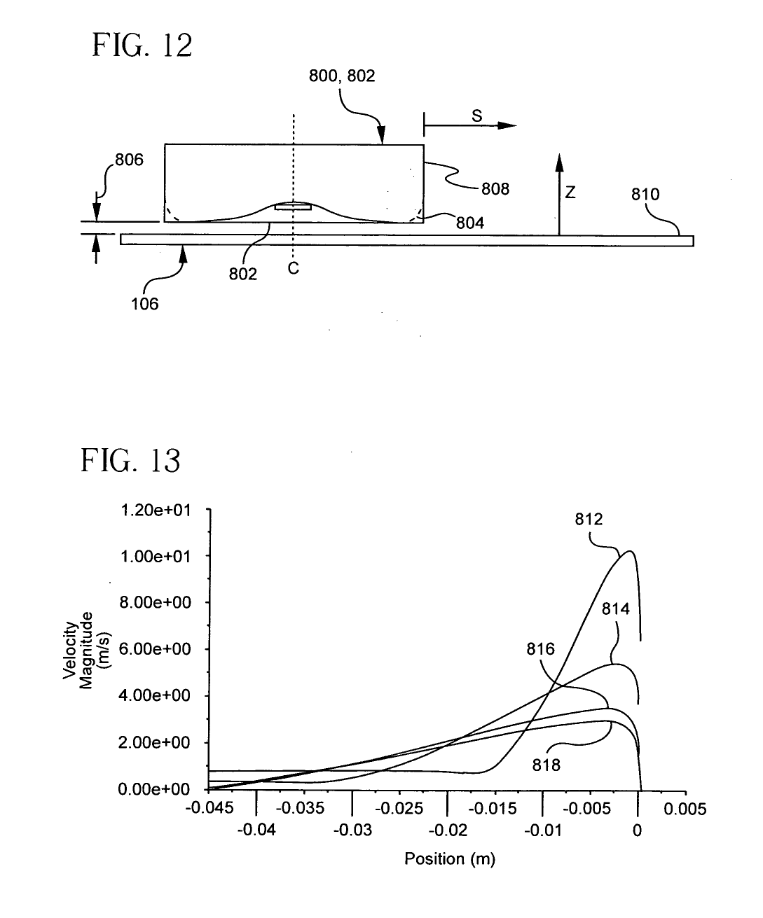

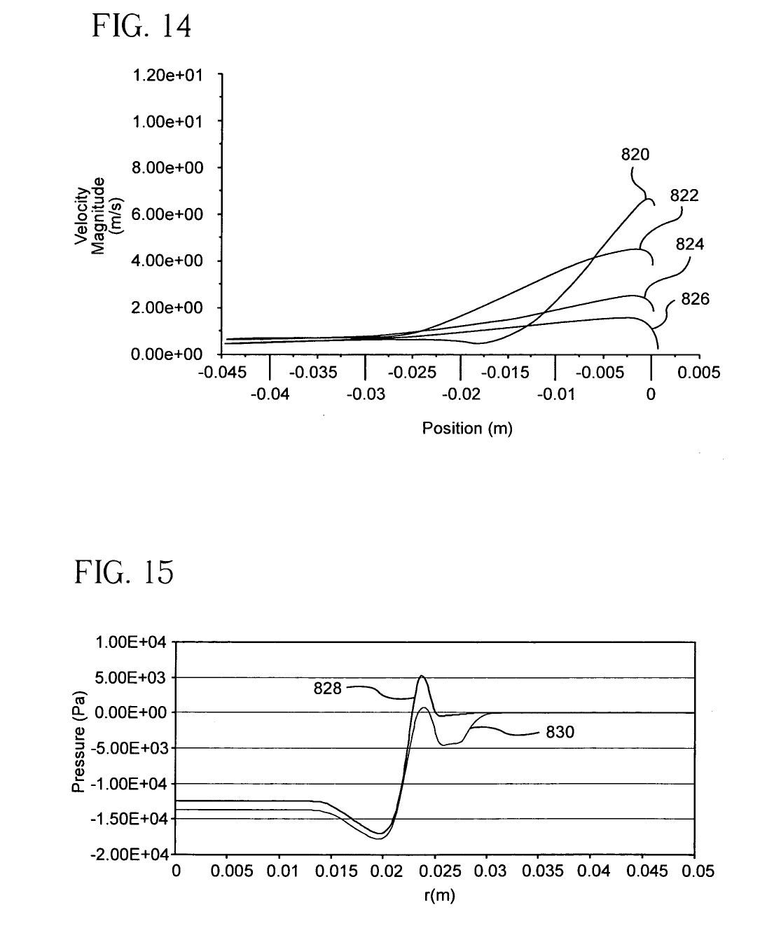

FLUENT software was used to model the velocity of air exiting between a pickup surface of a conventional aero-mechanical device using the Bernoulli principal and a modified aero-mechanical device to better understand the potential for velocity-induced turbulence that could lead to vibration of the glass sheet. The experiment can be better understood with the help of FIG. 12. The conventional aero-mechanical device 800 was a Rexroth NCT60 device. The modified device 802 was the same device, but with a rounded lower edge (pickup surface edge) 804 with a radius of curvature of approximately ⅛ inch (0.3175 cm). Both devices were assumed to be supplied with air at an inlet pressure of 6 bar. The velocity of the air exiting the gap 806 at reference surface 808 of each device is plotted in FIGS. 13 and 14, respectively, as a function of velocity in meters/second vs. distance Z from the surface 810 of glass sheet 106 (movement in a negative direction on the x-axis is in a direction away from the sheet). Curves 812, 814, 816 and 818 in FIG. 13 represent velocity as a function of distance from glass surface 810 at four radial distances S from surface 808 of the conventional aero-mechanical device 800: 10 cm, 20 cm, 30 cm and 35 cm, respectively. Curves 820, 822, 824 and 826 in FIG. 14 represent velocity as a function of distance from glass surface 810 at four radial distances S from surface 808 of the modified aero-mechanical device 802 at 10 cm, 20 cm, 30 cm and 35 cm, respectively. As shown, the velocity curves 820, 822, 824 and 826 for the modified device show a reduced velocity for all four positions (from surface 808) when compared to the conventional device, indicating a potential for reduced turbulence and subsequently reduced vibration of the glass, and less interaction between spaced apart devices used against the same glass sheet (and thus the ability to use multiple modified devices with reduced spacing when compared to conventional devices).

### EXAMPLE 3

Using FLUENT software, pressure against glass surface 810 was modeled for the conventional and modified devices 800 and 802, respectively, of the above Example 2, and again referring to FIG. 12. The data is plotted in FIG. 15 is pressure in Pascal as a function of radial distance (in meters) from the center of the devices, where a zero value on the x-axis represents the center axis C of the devices. Gap 806 was assumed to be 0.0005 m. Curve 828 depicts pressure as a function of radial distance for the conventional device 800, whereas curve 830 depicts pressure as a function of radial distance for the modified device 802. Surface 808 corresponds to a position of 0.03 m on the x-axis. As can be seem from the data, the conventional device experiences a significant positive pressure “bump” at a radial position of about 0.024 m, whereas the modified device 802 shows only a very small positive pressure at the same position, thus leading to the conclusion that the modified device (and a rounded edge), can provide greater holding force.

It should be emphasized that the above-described embodiments of the present invention, particularly any “preferred” embodiments, are merely possible examples of implementations, merely set forth for a clear understanding of the principles of the invention. For example, although much of the above description involved handling the glass sheet at the bottom of the draw area, embodiments of the present invention may be used at other times that large thin glass sheets must be handled. Many variations and modifications may be made to the above-described embodiments of the invention without departing substantially from the spirit and principles of the invention. All such modifications and variations are intended to be included herein within the scope of this disclosure and the present invention and protected by the following claims.

What is claimed is:

1. An aero-mechanical device comprising:
a body portion comprising an inlet for receiving a gas;
a cavity defined by the body portion in fluid communication with the inlet for equalizing a velocity of the gas;
an outlet orifice in fluid communication with the cavity for expelling the gas;
a distribution disk for distributing the gas expelled through the outlet orifice; and
wherein a radius of the cavity is equal to or greater than a radius of the distribution disk.

2. The aero-mechanical device according to claim 1 wherein the body portion comprises a pickup surface and an outside edge of the pickup surface is rounded.

3. The aero-mechanical device according to claim 2 wherein a radius of curvature of the outside edge is at least about 0.3 cm.

4. The aero-mechanical device according to claim 1 wherein the pickup surface is non-planar.

5. The aero-mechanical device according to claim 1 further comprising a porous annular region adapted to expel a gas disposed about the body portion.

6. The aero-mechanical device according to claim 1 wherein an outside edge of the porous annular region has a radius of curvature of at least about 0.3 cm.

7. A system for conveying a glass sheet comprising:
a robot comprising;
a plurality of aero-mechanical devices to support and hold the glass sheet without contacting the sheet, each of the plurality of aero-mechanical devices comprising a body portion defining a cavity disposed therein, an inlet orifice and an outlet orifice in fluid communication with the cavity for respectively receiving and expelling a gas, and a distribution disk for distributing the expelled gas;
a temperature control system for regulating a temperature of the gas emitted from the plurality of aero-mechanical devices; and
wherein a radius of the cavity is equal to or greater than a radius of the distribution disk.

8. The system according to claim 7 wherein the aero-mechanical device further comprises a porous annular region disposed about the body portion.

9. The system according to claim 7 wherein the body portion comprises a pickup surface, and a radius of curvature of an edge of the pickup surface is at least about 0.3 cm.

10. The system according to claim 8 wherein a radius of curvature of an edge of the porous annular region is at least about 0.3 cm.

11. The system according to claim 7 further comprising a position sensor for measuring a position of the aero-mechanical device relative to the glass sheet.

12. An apparatus for conveying a substrate comprising:
a robot;
a plurality of aero-mechanical devices connected to the robot, each of the plurality of aero-mechanical devices comprising a body portion defining a cavity disposed therein, an inlet orifice and an outlet orifice in fluid communication with the cavity for respectively receiving and expelling a gas, a distribution disk for distributing the expelled gas and a pickup surface; and
wherein a diameter of the cavity is equal to or greater than a diameter of the distribution disk.

13. The apparatus according to claim 12 wherein an edge of the pickup surface is rounded.

14. An apparatus for engaging and conveying a glass sheet comprising:
a robot including:
a plurality of aero-mechanical devices connected to the robot for emitting a gas toward a surface of the glass sheet, the plurality of aero-mechanical devices being adjacent to and supporting substantially an entire outer perimeter of the glass sheet, thereby flattening the sheet; and
a temperature control system for regulating a temperature of the gas emitted from the plurality of aero-mechanical devices.

15. The apparatus according to claim 12 wherein the plurality of aero-mechanical devices are adjacent to and supporting substantially an entire surface of the glass sheet.

16. The apparatus according to claim 12 wherein each of the aero-mechanical devices includes vacuum ports to which a vacuum is applied.

17. The apparatus according to claim 12 further comprising a porous member adapted to receive and expel a gas for supporting an edge of the glass sheet without contacting the sheet.

18. The apparatus according to claim 12 further comprising a member including a channel for supporting an edge of the glass sheet.

19. A method of acquiring a glass sheet comprising;
providing a glass sheet having opposing first and second sides and an edge substantially perpendicular to the sides;
moving an aero-mechanical device such that a pickup surface of the aero-mechanical device is at an index position proximate the first side of the glass sheet; and
moving the pickup surface from the index position in a direction toward the first side of the glass sheet while simultaneously increasing a pressure of a gas supplied to the aero-mechanical device to acquire and hold the glass sheet without contacting the sheet.

20. The method according to claim 19 wherein the index position is no more than about 3 mm from the surface of the glass sheet.

21. The method according to claim 19 wherein the providing a glass sheet comprises forming the glass sheet by a fusion downdraw process.

22. The method according to claim 19 further comprising scoring and separating the glass sheet after moving the pickup surface from the index position.
